(19) United States
(12) Patent Application Publication
(10) Pub. No.: US 2005/0082663 A1
(43) Pub. Date: Apr. 21, 2005

(54) Semiconductor device and semiconductor module

(75) Inventors: Satoru Wakiyama, Hyogo (JP); Kozo Harada, Hyogo (JP); Michitaka Kimura, Hyogo (JP)

Correspondence Address: McDermott, Will & Emery LLP, 600 13th Street, N.W., Washington, DC, 20005-3096, US

(73) Assignee: RENESAS TECHNOLOGY CORP.

(21) Appl. No.: 10/963,530

(22) Filed: Oct. 14, 2004

(30) Foreign Application Priority Data
Oct. 20, 2003 (JP) 2003-359007(P)

(51) Int. Cl. H01L 23/34

(52) U.S. Cl. 257/717

(57) ABSTRACT

A semiconductor device includes a flexible printed circuit board which is formed into a cylindrical shape so that a heat releasing space is formed therein, a plurality of semiconductor elements which are mounted on the inner surface of the flexible printed circuit board via inner bumps, and an external electrode (external terminal) which is provided on the flexible printed circuit board and which connects a wire on the flexible printed circuit board to an external wire on a mounting board. Herein, the heat releasing space is provided with a cooler for cooling the space.

### BACKGROUND OF THE INVENTION

1. Field of the Invention

The present invention relates to a semiconductor device and a semiconductor module. More particular, the present invention relates to a semiconductor device and a semiconductor module which have a transformable, flexible printed circuit board.

2. Description of the Background Art

A semiconductor device on which a plurality of chips have been mounted has been conventionally used in order to reduce the mounting area.

An increase in the integration and an enhancement of heat reducing properties become an important issue in a semiconductor device on which a plurality of semiconductor elements are mounted.

In the case where a plurality of chips are, for example, placed on the same plane, measures may be considered to increase the respective intervals between the chips or to increase the size of the radiators by using heat spreaders or the like in order to secure the heat releasing properties. As a result of this, a large space for the mounting area becomes necessary and the integration cannot be sufficiently increased.

Conventional semiconductor devices and semiconductor modules are disclosed in, for example, Japanese Patent Laying-Open No. 08-321580 (Conventional Example 1), Japanese Patent Laying-Open No. 2002-093988 (Conventional Example 2), Japanese Patent Laying-Open No. 10-150065 (Conventional Example 3), and Japanese Patent Laying-Open No. 08-111575 (Conventional Example 4).

Conventional Example 1 discloses a semiconductor device which includes an electronic component mounted on a flexible printed circuit board that is bent in a reversed U shape, a support provided to connect the flexible printed circuit board to another board, and a case that is mounted on the support so as to contain the flexible printed circuit board.

Conventional Example 2 discloses a semiconductor integrated circuit package (semiconductor device) which includes a plurality of flexible printed circuit boards on which semiconductor chips have been mounted, a connection terminal group formed along one side of each of the flexible printed circuit boards, and radiator plates adhering to the semiconductor chips, wherein cooling wind paths are formed between the radiator plates and the adjacent flexible printed circuit boards.

Conventional Example 3 discloses a chip size package (semiconductor device) which includes a semiconductor chip on which a plurality of electrodes are placed, a flexible printed circuit board placed in both planes on which the electrodes of the semiconductor chip are formed and which is perpendicular to the plane on which the electrodes of the semiconductor chip are formed, and solder balls aligned on the flexible printed circuit board for being soldered to a wiring board, wherein the flexible printed circuit board have through holes from which the electrodes of the semiconductor chip are exposed so that the electrodes exposed from these through holes and the wires of the flexible printed circuit board are connected by means of wire pads.

Conventional Example 4 discloses a semiconductor device wherein a semiconductor element is mounted on a board that includes a wiring layer, one end of the board is bent to a J shape or L shape so that the surface on which the semiconductor element is mounted becomes the external side of the bent board, and the wiring layer of the bent portion of the board and the wires on a mother board are electrically connected so that the board is mounted on the mother board.

However, the following problems arise in the above-described semiconductor devices.

In the semiconductor device according to Conventional Example 1, the flexible printed circuit board and the mounting board are connected via the support having lead terminals; therefore, an increase in the mounting density is limited in some cases.

In the semiconductor device according to Conventional Example 2, cooling wind paths are formed by using radiator plates and no ideas are disclosed where heat releasing spaces are formed by transforming the flexible printed circuit board. Therefore, in some cases, the size of the semiconductor device is increased, limiting an increase in the integration.

In the semiconductor device according to Conventional Example 3, only one semiconductor chip is placed on one flexible printed circuit board and no ideas are disclosed where a plurality of semiconductor chips are mounted on one flexible printed circuit board.

In the semiconductor device according to Conventional Example 4, no ideas are disclosed where a heat releasing space is formed within a flexible printed circuit board that has been formed into a cylindrical shape so that the heat generated by the semiconductor element is released.

As described above, the semiconductor devices according to Conventional Examples 1 to 4 and the semiconductor device according to the present invention have completely different presuppositions.

### SUMMARY OF THE INVENTION

The present invention is made in view of the above problems, and an object of the present invention is to provide a semiconductor device which is appropriate for an increase in the integration and which is excellent in heat releasing properties, as well as a semiconductor module having such a semiconductor device.

The semiconductor device according to the present invention includes: a flexible printed circuit board formed into a cylindrical shape so that a heat releasing space is formed therein; a plurality of semiconductor elements mounted on an inner surface of the flexible printed circuit board; a cooler for cooling the heat releasing space; and an external terminal which is provided on the flexible printed circuit board and which connects a wire on the flexible printed circuit board to an external wire.

The semiconductor module according to the present invention is formed by mounting a plurality of semiconductor devices, each of which is the above-described semiconductor device, on a wiring printed circuit board having another external terminal.

According to the present invention, the mounting area of a semiconductor device can be reduced and the effect of releasing heat generated by energizing a semiconductor element can be enhanced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view showing a flexible printed circuit board on which a plurality of semiconductor elements have been mounted via inner bumps;

FIG. 2 is a top view of the flexible printed circuit board shown in FIG. 1;

FIGS. 3A and 3B are views showing a semiconductor device that is formed by bending a flexible printed circuit board on which a plurality of semiconductor elements have been mounted into a cylindrical shape, wherein FIG. 3A is a cross sectional view in the axial direction and FIG. 3B is a perspective view;

FIGS. 4A-6B are views showing a semiconductor device according to first, second and third embodiments, respectively, of the present invention, wherein FIGS. 4A, 5A and 6A are cross sectional views in the axial direction and FIGS. 4B, 5B and 6B are perspective views;

FIGS. 7A, 7B and 7C are views showing a semiconductor device according to a fourth embodiment of the present invention, wherein FIG. 7A is a side view in the axial direction, FIG. 7B is a top view, and FIG. 7C is a side view; and

FIGS. 8-13 are cross sectional views showing a semiconductor device according to fifth, sixth, seventh, eighth, ninth and tenth embodiments, respectively, of the present invention.

### DESCRIPTION OF THE PREFERRED EMBODIMENTS

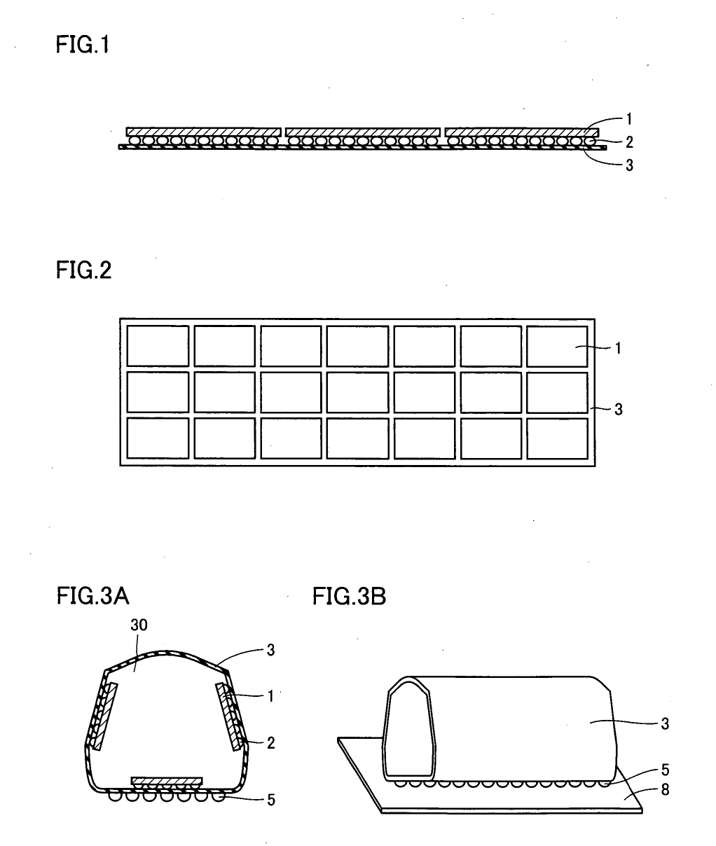

In the following, semiconductor devices and semiconductor modules according to the embodiments of the present invention will be described with reference to FIGS. 1 to 13.

### FIRST EMBODIMENT

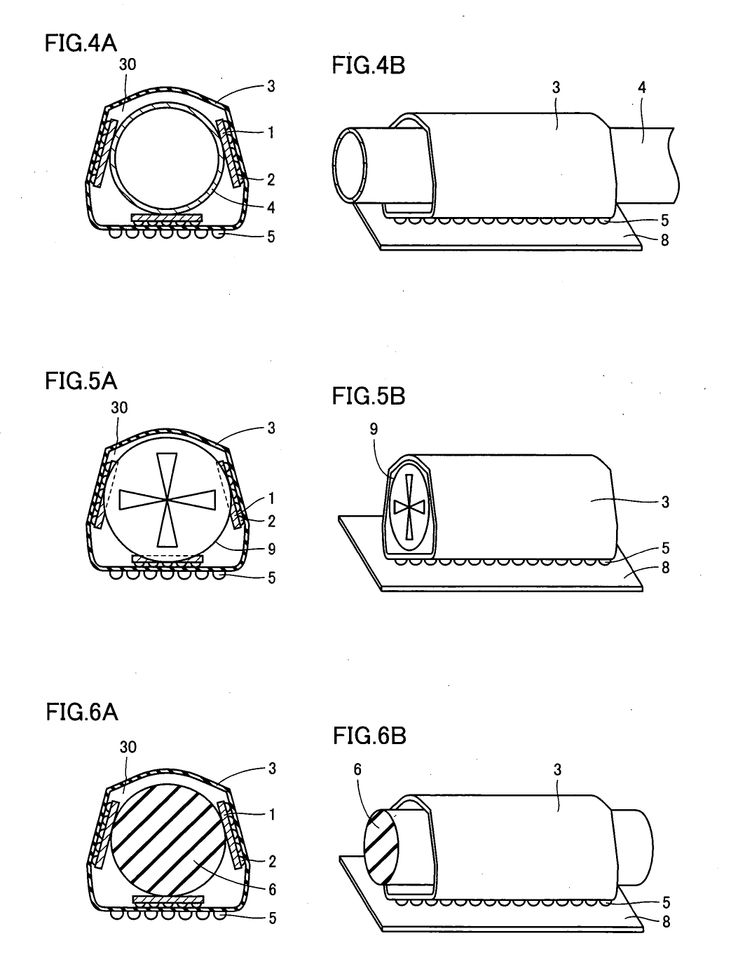

FIG. 1 is a cross sectional view showing a flexible printed circuit board 3 on which the plurality of semiconductor elements 1 are mounted via inner bumps 2, and FIG. 2 is a top view showing this flexible printed circuit board 3.

Flexible printed circuit board 3 includes a film layer made of, for example, polyester or polyimide, and can be rolled or bent. Flexible printed circuit board 3 on which semiconductor elements 1 have been mounted as shown in FIGS. 1 and 2 is formed into, for example, a cylindrical shape or an L shape; thereby, a space that is required for this flexible printed circuit board at the time when being mounted on a mounting board can be reduced. As a result of this, the mounting area of the semiconductor device can be reduced.

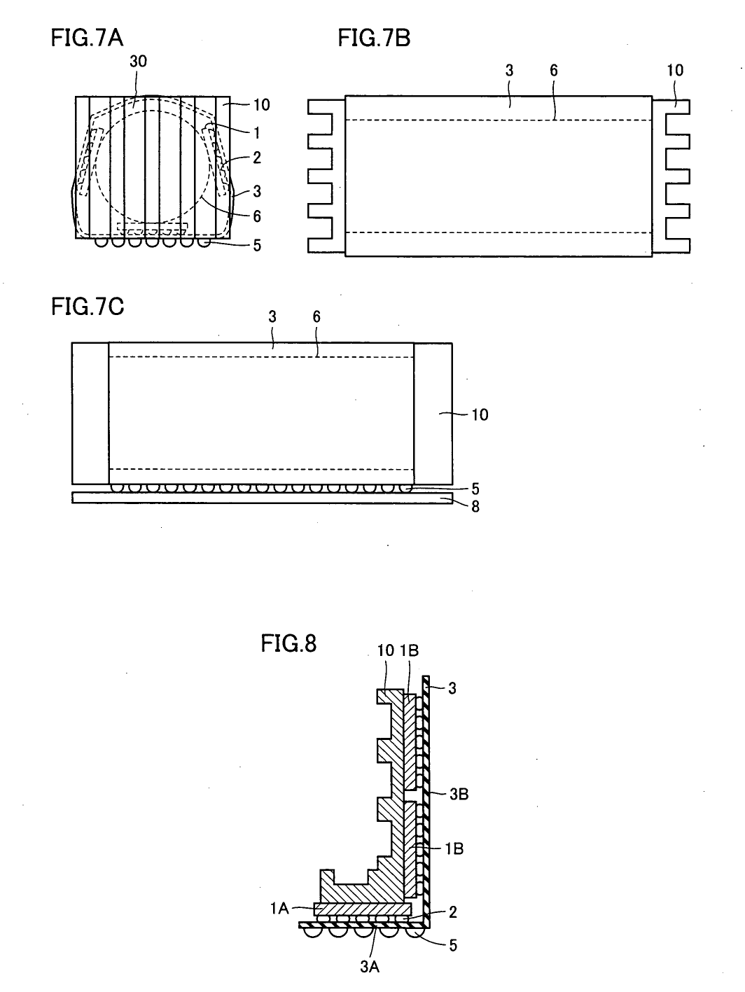

FIGS. 3A and 3B are views showing a semiconductor device in cylindrical shape into which flexible printed circuit board 3 on which the plurality of semiconductor elements 1 have been mounted is bent, wherein FIG. 3A is a cross sectional view in the axial direction and FIG. 3B is a perspective view.

The semiconductor device according to the present embodiment includes, as shown in FIGS. 3A and 3B, flexible printed circuit board 3 formed into a cylindrical shape so that a heat releasing space 30 is formed inside, the plurality of semiconductor elements 1 that have been mounted on the inner surface of flexible printed circuit board 3 via inner bumps 2, and an external electrode 5 (external terminal) which is provided on flexible printed circuit board 3 and which connects a wire on flexible printed circuit board 3 to an external wire on a mounting board 8. Here, a cooler for cooling this space is provided in heat releasing space 30.

In the above-described configuration, the mounting area of the semiconductor device can be reduced. In addition, heat releasing space 30 can be utilized in order to cool semiconductor elements 1 that have generated heat by being energized. Furthermore, the above-described cooling effect can be enhanced by providing a cooler within heat releasing space 30.

Here, the above-described cylindrical shape is not limited to the one having a cross sectional form as shown in FIG. 3A, but rather a circular form, a triangular form or other polygonal forms, for example, can be used.

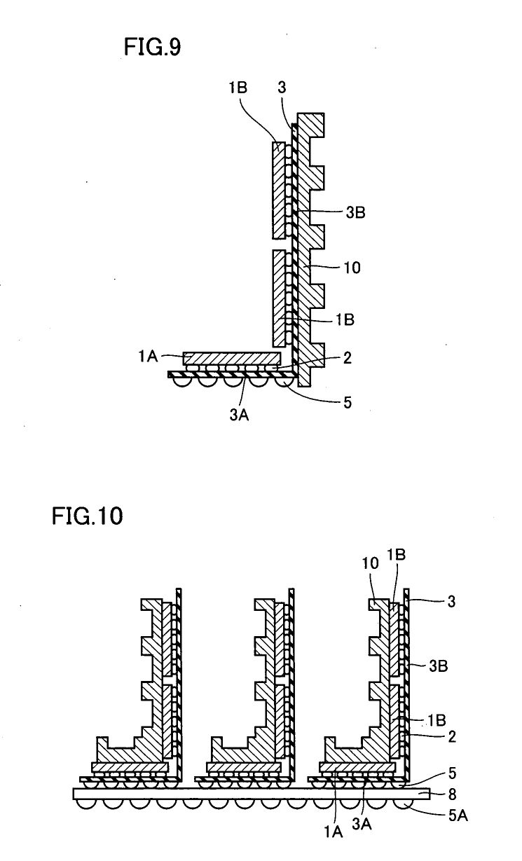

FIGS. 4A and 4B are views showing the condition where a cooling pipe 4 as a cooler is provided within heat releasing space 30 of the semiconductor device shown in FIG. 3, wherein FIG. 4A is a cross sectional view in the axial direction and FIG. 4B is a perspective view.

Here, cooling water or a cooling medium that includes an organic solvent such as methanol or acetone, for example, is supplied into the cooling pipe. The cooling pipe forms a circular circuit starting from the inside of heat releasing space 30 and reaching the outside of this space, wherein the cooling medium circulates within the circular circuit by means of a circulator such as a pump. The cooling medium absorbs heat that is generated by semiconductor elements 1 within heat releasing space 30 so as to be cooled outside heat releasing space 30.

Semiconductor elements 1 include semiconductor chips and semiconductor packages, and are mounted on flexible printed circuit board 3 by means of flip chip connection via inner bumps 2 made of, for example, solder balls. As a result of this, wires formed within semiconductor elements 1 and wires formed on flexible printed circuit board 3 are connected to each other. In addition, flexible printed circuit board 3 in cylindrical shape is mounted on a mounting board 8 via external electrodes 5 made of, for example, solder balls. As a result of this, wires formed on flexible printed circuit board 3 and wires formed on mounting board 8 are connected to each other.

It is preferable for inner bumps 2 and external electrodes 5 to be protected by an underfill resin that fills the space under semiconductor elements 1 and under flexible printed circuit board 3 in order to enhance resistance to heat in the reflow process.

Here, a structure may be introduced where semiconductor elements 1 are mounted on flexible printed circuit board 3 by means of wire bonding.

In accordance with the present embodiment, the mounting area of the semiconductor device can be reduced in the above-described configuration. In addition, the efficiency of the release of heat that is generated by the semiconductor elements can be increased by installing a cooling pipe; therefore, the effect of preventing malfunction and the deterioration of the functions of the semiconductor device can be enhanced.

### SECOND EMBODIMENT

FIGS. 5A and 5B are views showing the semiconductor device according to a second embodiment of the present invention, wherein FIG. 5A is a cross sectional view in the axial direction and FIG. 5B is a perspective view.

With reference to FIGS. 5A and 5B, the semiconductor device according to the present embodiment is a modification of the semiconductor device according to the first embodiment, and is different from the semiconductor device according to the first embodiment in the point where cooling fans 9 are provided as the above-described cooler in end portions of the heat releasing space in the axial direction.

Here, the cooling fans allow air to flow from the outside into heat releasing space 30. As a result of this, cool air is sent from the outside into the heat releasing space that has been heated by the energized semiconductor elements so that heat releasing space 30 is cooled.

In addition, cooling fan 9 may be installed only in one end portion of the heat releasing space.

Here, the other portions of the semiconductor device are the same as those according to the first embodiment; therefore, detailed description thereof will not be repeated.

According to the present embodiment, the mounting area of the semiconductor device can be reduced in the above-described configuration, in the same manner as in the first embodiment. In addition, the efficiency of the release of heat that is generated by the semiconductor elements can be increased by installing cooling fans; thereby, malfunction and the deterioration of the functions of the semiconductor device can be prevented.

### THIRD EMBODIMENT

FIGS. 6A and 6B are views showing the semiconductor device according to a third embodiment of the present invention, wherein FIG. 6A is a cross sectional view in the axial direction and FIG. 6B is a perspective view.

With reference to FIGS. 6A and 6B, the semiconductor device according to the present embodiment is a modification of the semiconductor devices according to each of the above embodiments, and is different from the semiconductor devices according to each of the above embodiments in the point where a radiator 6 that extends in the axial direction of heat releasing space 30 is provided as the above-described cooler within the space.

Here, a high water absorbing resin in gel form or a silicone resin that includes a metal filler, for example, can be considered as radiator 6. Here, the above-described high water absorbing resin can be obtained as a result of a cross linking response of a monomer such as methacrylic acid. In addition, the high water absorbing resin absorbs water or an organic solvent. Though an organic solvent having a low boiling point can be utilized as such an organic solvent, it is preferable to use an organic solvent having a high boiling point (e.g., approximately 300° C. or higher), taking the reflow temperature (e.g., approximately 260° C.) into consideration.

In addition, it is also possible to use a resin body that does not include a metal filler or a metal body, as a radiator.

Here, the other parts of the semiconductor device are the same as those according to each of the above embodiments; therefore, detailed description thereof will not be repeated.

In accordance with the present embodiment, the mounting area of the semiconductor device can be reduced in the above-described configuration in the same manner as in each of the above embodiments. In addition, the efficiency of the release of heat that is generated by the semiconductor elements can be increased by installing a radiator; therefore, the effect of preventing malfunction and the deterioration of the functions of the semiconductor device can be enhanced.

### FOURTH EMBODIMENT

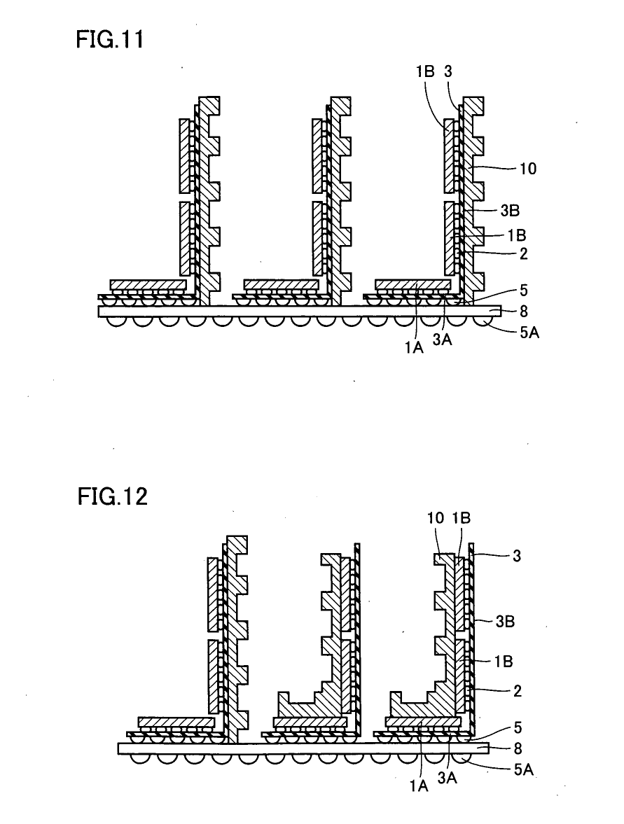

FIGS. 7A, 7B and 7C are views showing the semiconductor device according to a fourth embodiment of the present invention, wherein FIG. 7A is a side view in the axial direction, FIG. 7B is a top view and FIG. 7C is a side view.

With reference to FIGS. 7A, 7B and 7C, the semiconductor device according to the present embodiment is a modification of the semiconductor device according to the third embodiment, and is different from the semiconductor device according to the third embodiment in the point that radiator 6 extends to reach the two end portions of heat releasing space 30 in the axial direction and heat sinks 10 are attached to both end portions of flexible printed circuit board 3.

Here, heat sinks 10 are connected to both ends of flexible printed circuit board 3 in the axial direction by means of an adhesive. It is preferable for the used adhesive to have excellent heat releasing properties.

In the above-described configuration, the heat generated by semiconductor elements 1 reaches heat sinks 10 via radiator 6 so as to be released to the outside. That is to say, radiator 6 and heat sinks 10 function as coolers.

Here, the other parts of the semiconductor device are the same as those according to each of the above embodiments; therefore, detailed description thereof will not be repeated.

In accordance with the present embodiment, the mounting area of the semiconductor device can be reduced in the above-described configuration in the same manner as in the third embodiment. In addition, the efficiency of the release of heat that is generated by the semiconductor elements can be increased; therefore, the effect of preventing malfunction and the deterioration of the functions of the semiconductor device can be enhanced.

In addition, the area exposed to the air outside of heat releasing space 30 is increased by installing heat sinks 10; thereby, a further increase in heat releasing properties of semiconductor elements 1 become possible.

Here, a structure may be introduced where radiator 6 extends so as to reach only one end portion of heat releasing space 30 in the axial direction, and a heat sink 10 is attached only to the end portion of flexible printed circuit board 3 on the side where radiator 6 reaches to the end portion of heat releasing space 30. In this case, the same effects as described above are obtained.

### FIFTH EMBODIMENT

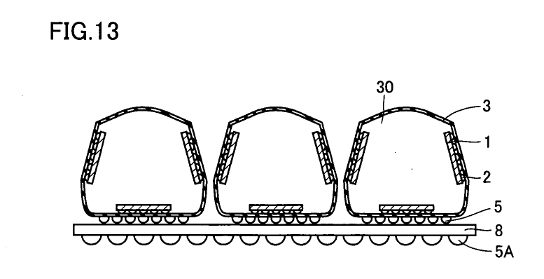

FIG. 8 is a cross sectional view showing the semiconductor device according to a fifth embodiment of the present invention.

With reference to FIG. 8, the semiconductor device according to the present embodiment includes: a flexible printed circuit board 3 having a connected portion 3A that is connected to a mounting board, and a rising portion 3B that rises from one end of connected portion 3A; an external electrode 5 (external terminal) which is provided to connected portion 3A and which connects a wire on flexible printed circuit board 3 to an external wire on the mounting board; a semiconductor element 1A which is a first semiconductor element mounted on connected portion 3A; semiconductor elements 1B which are second semiconductor elements mounted on the rising portion; and a heat sink 10 (heat releasing member) which supports rising portion 3B and which has a heat releasing function.

In this configuration, the mounting area of the semiconductor device can be reduced. In addition, heat releasing properties for releasing the heat that is generated by semiconductor elements 1A and 1B can be secured by means of heat sink 10. Furthermore, the semiconductor elements are installed on both the connected portion and the rising portion; thereby, the effects of reducing the mounting area while securing the heat releasing properties can be further be enhanced.

In addition, in FIG. 8, heat sink 10 (heat releasing member) is provided so as to extend from a portion on semiconductor element 1A (first semiconductor element) to portions on semiconductor elements 1B (second semiconductor elements). Concretely speaking, heat sink 10 extends along connected portion 3A and rising portion 3B of flexible printed circuit board 3, and semiconductor elements 1A, 1B and inner bumps 2 are supported between heat sink 10 and flexible printed circuit board 3.

Inner bumps 2 connect wires formed within semiconductor elements 1A and 1B to wires formed on flexible printed circuit board 3. In addition, external electrodes 5 connect wires formed on flexible printed circuit board 3 to wires formed on the mounting board.

It is preferable for inner bumps 2 and external electrodes 5 to be protected by an underfill resin that fills the space under semiconductor elements 1A and 1B, and under flexible printed circuit board 3, in order to enhance resistance to heat in the reflow process.

Heat sink 10 is adhered to semiconductor elements 1A and 1B by means of an adhesive. It is preferable for the used adhesive to have excellent heat releasing properties.

In the above-described configuration, heat sink 10 can be used as a structural support in the semiconductor device.

In accordance with the present embodiment, flexible printed circuit board 3 has connected portion 3A and rising portion 3B; thereby, the mounting area of the semiconductor device can be reduced. Here, heat sink 10 is provided within a space formed between connected portion 3A and rising portion 3B of flexible printed circuit board 3; thereby, the heat releasing effects for releasing the heat that is generated by semiconductor elements 1A and 1B can be enhanced without increasing the mounting area.

### SIXTH EMBODIMENT

FIG. 9 is a cross sectional view showing the semiconductor device according to a sixth embodiment of the present invention.

The semiconductor device according to the present embodiment is a modification of the semiconductor device according to the fifth embodiment, and is different from the semiconductor device according to the fifth embodiment in the point where heat sink 10 (heat releasing member) is provided so as to stand on the opposite side of semiconductor elements 1B (second semiconductor elements) relative to rising portion 3B of flexible printed circuit board 3.

Here, heat sink 10 is adhered to rising portion 3B by means of an adhesive. It is preferable for the used adhesive to have excellent heat releasing properties.

In this configuration, heat sink 10 can be used as a structural support in the semiconductor device.

Here, the other parts of the semiconductor device are the same as those in the fifth embodiment; therefore, detailed description thereof will not be repeated.

In accordance with the present embodiment, flexible printed circuit board 3 has connected portion 3A and rising portion 3B; thereby, the mounting area of the semiconductor device can be reduced in the same manner as in the fifth embodiment. Here, heat sink 10 is provided on the surface of rising portion 3B on the opposite side of semiconductor elements 1B; thereby, the degree of freedom of mounting semiconductor elements 1B on rising portion 3B can be increased. As a result of this, an increase in the integration of the semiconductor device is facilitated.

### SEVENTH EMBODIMENT

FIG. 10 is a cross sectional view showing the semiconductor module according to a seventh embodiment of the present invention.

The semiconductor module in accordance with the present embodiment is formed by mounting a plurality of semiconductor devices (three semiconductor devices), each of which is the same semiconductor device as the one according to the fifth embodiment, on a mounting board 8 having external electrodes 5A (other external terminals).

External electrodes 5A are formed of, for example, solder balls and connect wires formed on mounting board 8 to wires formed on a mother board (not shown).

It is preferable for inner bumps 2 and external electrodes 5 and 5A to be protected by an underfill resin that fills the space under semiconductor elements 1A and 1B, flexible printed circuit board 3, and mounting board 8, in order to enhance resistance to heat in the reflow process.

As described above, this semiconductor module allows the mounting area to be reduced, and has a structure with excellent heat releasing properties. In addition, the semiconductor devices form a module; thereby, mounting the semiconductor devices on a mother board is facilitated.

Here, the number (three in the present embodiment) of the semiconductor devices mounted on mounting board 8 can be changed to an arbitrary number.

### EIGHTH EMBODIMENT

FIG. 11 is a cross sectional view showing the semiconductor module according to an eighth embodiment of the present invention.

The semiconductor module in accordance with the present embodiment is a modification of the semiconductor module according to the seventh embodiment, and is formed by mounting a plurality of semiconductor devices (three semiconductor devices), each of which is the same semiconductor device as that in the sixth embodiment, on mounting board 8.

Here, the other parts of the semiconductor module are the same as those in the seventh embodiment; therefore, detailed description thereof will not be repeated.

In such a configuration, the same effects as in the seventh embodiment are obtained.

### NINTH EMBODIMENT

FIG. 12 is a cross sectional view showing the semiconductor module according to a ninth embodiment of the present invention.

The semiconductor module in accordance with the present embodiment is a modification of the semiconductor modules according to the seventh and eighth embodiments, and is provided with (two) semiconductor devices, each of which is the same semiconductor device as that according to the fifth embodiment, and a (one) semiconductor device which is the same as that according to the sixth embodiment, which are mounted on mounting board 8.

Here, the other parts of the semiconductor module are the same as those according to the seventh and eighth embodiments; therefore, detailed description thereof will not be repeated.

As described above, the same effects as in the seventh and eighth embodiments are obtained in a configuration where different types of semiconductor devices are mixed on mounting board 8.

Here, it is possible to change the order of the arrangement of the above-described different types of semiconductor devices to an arbitrary order.

### TENTH EMBODIMENT

FIG. 13 is a cross sectional view showing the semiconductor module according to a tenth embodiment of the present invention.

The semiconductor module in accordance with the present embodiment is a modification of the semiconductor modules according to the seventh to ninth embodiments, and is formed by mounting a plurality of semiconductor devices (three semiconductor devices), each of which is the same as the one according to one of the first to fourth embodiments, on mounting board 8.

In FIG. 13, though a cooler provided within heat releasing space 30 is not shown, it is possible to install an arbitrary cooler from among those described in the first to fourth embodiments.

In addition, a plurality of semiconductor devices having different types of coolers may be mixed on mounting board 8.

Here, the other parts of the semiconductor module are the same as those according to the seventh to ninth embodiments; therefore, detailed description thereof will not be repeated.

In such a configuration, the same effects as in the seventh to ninth embodiments are obtained.

Features of the semiconductor devices and semiconductor modules as described in the above embodiments can be combined as appropriate.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising:
a flexible printed circuit board formed into a cylindrical shape so that a heat releasing space is formed therein;
a plurality of semiconductor elements mounted on an inner surface of said flexible printed circuit board;
cooling means for cooling said heat releasing space; and
an external terminal which is provided on said flexible printed circuit board and which connects a wire on the flexible printed circuit board to an external wire.

2. The semiconductor device according to claim 1, wherein
said cooling means includes a cooling pipe provided within said heat releasing space, and
a cooling medium is supplied into said cooling pipe.

3. The semiconductor device according to claim 1, further comprising:
a cooling fan provided on at least one end portion of said heat releasing space in an axial direction, wherein
said cooling fan allows air to flow from the outside into said heat releasing space.

4. The semiconductor device according to claim 1, further comprising:
a radiator which is provided within said heat releasing space and which extends in the axial direction of said heat releasing space.

5. The semiconductor device according to claim 4, wherein
said radiator extends so as to reach at least one end portion of said heat releasing space in the axial direction, and
a heat sink is attached to the end portion of said flexible printed circuit board on the side where said radiator has reached the end portion of said heat releasing space in the axial direction.

6. A semiconductor module comprising:
a plurality of semiconductor devices, each of which is the semiconductor device according to claim 1, mounted on a wiring board provided with another external terminal.

7. A semiconductor device comprising:
a flexible printed circuit board having a connected portion that is connected to a mounting board and a rising portion that rises from one end of the connected portion;
an external terminal which is provided to said connected portion and which connects a wire on said flexible printed circuit board to an external wire on said mounting board;
a first semiconductor element mounted on said connected portion;
a second semiconductor element mounted on said rising portion; and
a heat releasing member which supports said rising portion and which has a heat releasing function.

8. The semiconductor device according to claim 7, wherein
said heat releasing member is provided so as to extend from a portion on said first semiconductor element to a portion on said second semiconductor element.

9. The semiconductor device according to claim 7, wherein
said heat releasing member is erected on the opposite side of said second semiconductor element relative to said rising portion.

10. A semiconductor module comprising:
a plurality of semiconductor devices, each of which is the semiconductor device according to claim 7, mounted on a wiring board provided with another external terminal.
